(19) United States
(12) Patent Application Publication
(10) Pub. No.: US 2017/0047251 A1
(43) Pub. Date: Feb. 16, 2017

(54) METHOD OF MANUFACTURING A SEMICONDUCTOR DEVICE INCLUDING FORMING A DIELECTRIC LAYER AROUND A PATTERNED ETCH MASK

(71) Applicant: United Microelectronics Corp., Hsin-Chu City (TW)

(72) Inventors: Yi-Hui Lee, Taipei City (TW); Kun-Ju Li, Tainan City (TW); Wei-Cyuan Lo, Taichung City (TW); Ching-Wen Hung, Tainan City (TW); Jia-Rong Wu, Kaohsiung City (TW); Ying-Cheng Liu, Tainan City (TW); Yi-Kuan Wu, Kaohsiung City (TW); Chih-Sen Huang, Tainan City (TW); Yi-Wei Chen, Taichung City (TW)

(21) Appl. No.: 14/824,091

(22) Filed: Aug. 12, 2015

(51) Int. Cl. H01L 21/768; H01L 21/311; H01L 29/78; H01L 21/3105

(52) U.S. Cl. CPC H01L 21/76895; H01L 21/76805; H01L 21/31051; H01L 21/31111; H01L 21/31133; H01L 21/31144; H01L 29/7851

(57) ABSTRACT

A method of manufacturing a semiconductor device includes: providing a semiconductor having active regions; depositing a dielectric layer on the semiconductor; forming a patterned etch mask on the dielectric layer; depositing a further dielectric layer on the dielectric layer and the patterned etch mask; planarizing the further dielectric layer until the patterned etch mask is exposed; and forming a further patterned etch mask having an opening on the further dielectric layer so that portions of the patterned etch mask are exposed from the opening.

### BACKGROUND OF THE INVENTION

1. Field of the Invention

The invention relates generally to a method for fabricating a semiconductor device, and more particularly to a method of forming contact openings by using orthogonal stripes as etch masks.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However, the yield rate in the process of fabricating contact structures is often low due to the deviation of the contours of corresponding contact openings. Hence, how to improve the current FinFET process, especially the process of fabricating contact structures, has become an important task in this field.

### SUMMARY OF THE INVENTION

A method of manufacturing a semiconductor device is disclosed according to one embodiment of the present application and includes the following steps: providing a semiconductor having active regions; depositing a dielectric layer on the semiconductor; forming a patterned etch mask on the dielectric layer; depositing a further dielectric layer on the dielectric layer and the patterned etch mask; planarizing the further dielectric layer until the patterned etch mask is exposed; and forming a further patterned etch mask having an opening on the further dielectric layer so that portions of the patterned etch mask are exposed from the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-10 illustrate a method for fabricating a semiconductor device according to a first preferred embodiment of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity unless express so defined herein. Moreover, each embodiment described and illustrated herein includes its complementary conductivity type embodiment as well. Like numbers refer to like elements throughout.

It will be understood that when an element or layer is referred to as being “on,” “engaged to, ” “connected to” and/or “coupled to” another element or layer, it can be directly on, engaged, connected or coupled to the other element or layer or intervening elements or layers may be presented. In contrast, when an element is referred to as being “directly on,” “directly engaged to,” “directly connected to” and/or “directly coupled to” another element or layer, there are no intervening elements or layers present. Other words used to describe the relationship between elements should be interpreted in a like fashion (e.g., “between” versus “directly between,” “adjacent” versus “directly adjacent,” etc.) As used herein, the term “and/or” may include any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

Spatially relative terms, such as “inner,” “outer,” “beneath,” “below,” “lower,” “above,” “upper” and the like, may be used herein for ease of description to describe one element and/or feature's relationship to another element(s) and/or feature(s) as illustrated in the figures. Spatially relative terms may be intended to encompass different orientations of the device in use or operation in addition to the orientation depicted in the figures. For example, if the device in the figures is turned over, elements described as “below” and/or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular terms “a”, “an,” and “the” may be intended to include the plural forms as well, unless the context clearly indicates otherwise. The terms “comprises,” “comprising,” “includes” and/or “including” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

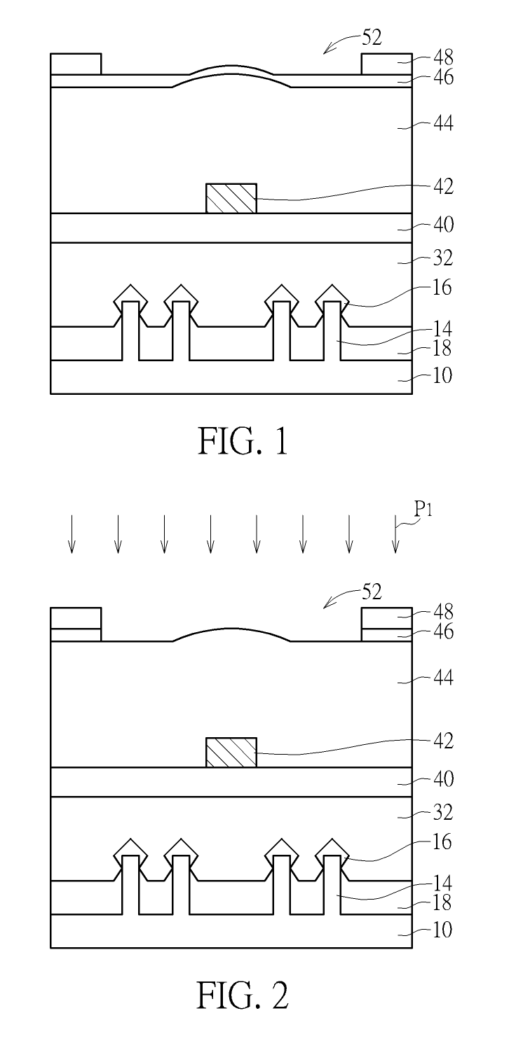

Referring to FIGS. 1-4, FIGS. 1-4 illustrate a method for fabricating a semiconductor device according to a first preferred embodiment of the present invention. As shown in FIG. 1, a substrate 10, such as a silicon substrate or silicon-on-insulator (SOI) substrate is provided, and a transistor region, such as a PMOS region or a NMOS region is defined on the substrate 10.

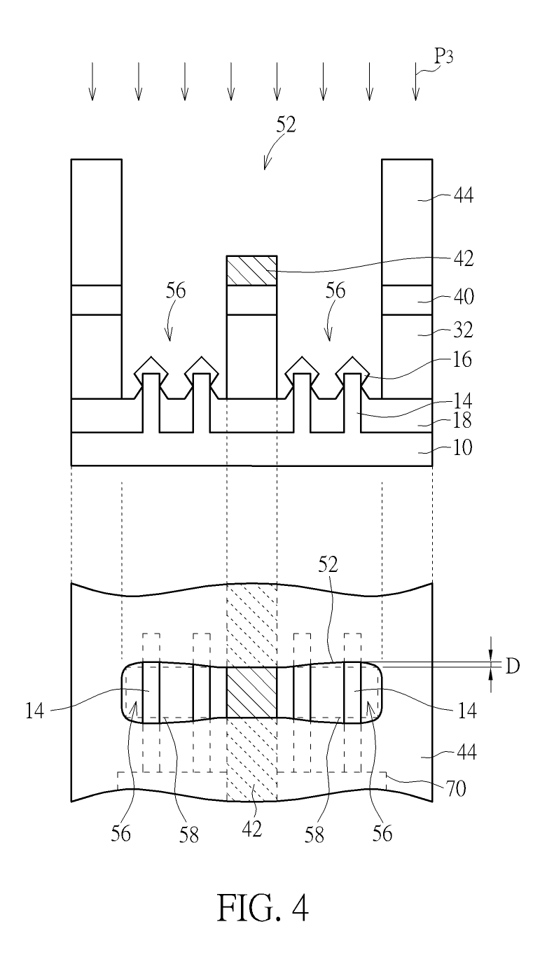

Several first fin-shaped structures 14 and an insulating layer 18 are formed on the substrate 10, in which the bottom of the fin-shapes structures 14 are preferably enclosed by the insulating layer 18, such as silicon oxide to form a shallow trench isolation (STI). At least a gate structure 70 (shown in FIG. 4), such as a metal gate, crosses portions of every fin-shaped structure 14. It should be noted that even though only one metal gate is disclosed in this embodiment, the quantity of the metal gate is not limited to one, but could by any quantity depending on the demand of the product.

The formation of the fin-shaped structures 14 could be accomplished by first forming a patterned mask (not shown) on the substrate 10, and an etching process is performed to transfer the pattern of the patterned mask to the substrate 10. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form an insulating layer surrounding the bottom of the fin-shaped structures 14. Alternatively, the formation of the fin-shaped structures 14 could also be accomplished by first forming a patterned hard mask (not shown) on the substrate 10, and then performing an epitaxial process on the exposed substrate 10 through the patterned hard mask to grow a semiconductor layer. This semiconductor layer could then be used as the corresponding fin-shaped structures 14. In another fashion, the patterned hard mask could be removed selectively or retained, and deposition, CMP, and then etching back could be used to form an insulating layer to surround the bottoms of the fin-shaped structures 14. Moreover, if the substrate 10 were a SOI substrate, a patterned mask could be used to etch a semiconductor layer on the substrate until reaching a bottom oxide layer underneath the semiconductor layer to form the corresponding fin-shaped structure.

The fabrication of the metal gate could be accomplished by a gate first process, a high-k first approach from gate last process, or a high-k last approach from gate last process. Since this embodiment pertains to a high-k last approach, dummy gate (not shown) composed of polysilicon material could be first formed on the fin-shaped structures 14 and the insulating layer, and a spacer (not shown) is formed on the sidewall of the dummy gate. A source/drain region and/or epitaxial layers 16 are then formed on the fin-shaped structures 14 and/or substrate 10 adjacent to two sides of the spacer, a contact etch stop layer (CESL) (not shown) may be optionally formed on the dummy gates, and an interlayer dielectric (ILD) layer 32 composed of tetraethyl orthosilicate (TEOS) or other suitable dielectric materials is formed on the CESL. Next, a replacement metal gate (RMG) process could be conducted to planarize part of the ILD layer 32 and CESL and then transforming the dummy gate into a metal gate.

In this embodiment, the metal gate preferably includes a high-k dielectric layer, a work function metal layer and a gate electrode. The work function metal layer is formed for tuning the work function of the later formed metal gates to be appropriate in an NMOS or a PMOS. For an NMOS transistor, the work function metal layer 34 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 34 and the low resistance metal layer 36, in which the material of the barrier layer may include titanium (Ti), titanium nitride (TiN), tantalum (Ta) or tantalum nitride (TaN). Furthermore, the material of the low-resistance metal layer 36 may include copper (Cu), aluminum (Al), titanium aluminum (TiAl), cobalt tungsten phosphide (CoWP) or any combination thereof.

Next, a dielectric layer 40 is formed on the ILD layer 32 and the metal gate. The dielectric layer 40 may be an oxide layer composed of tetraethyl orthosilicate (TEOS), but is not limited thereto. It may also be composed of other suitable dielectric materials.

Then, a patterned etch mask 42 is formed on the dielectric layer 40 and is used to define the positions of contact structures to be fabricated in the following processes. Specifically, the contact structures can only be formed in the ILD layer 32 not covered by the patterned etch mask 42. In addition, the patterned etch mask 42 may be made of any materials whose etching rates are less than one-third of the etching rates of the underlying layers, such as the dielectric layer 40, the ILD layer 32, and the CESL. Preferably, the patterned etch mask 42 has a long axis perpendicular to the plane of the paper and is made of at least one of Ti, TiN, Ta, TaN or other conductive materials, but is not limited thereto. It should be noted that the patterned etch mask 42 may include several discrete masks separately disposed on the dielectric layer 40. These discrete masks are preferably electrically isolated from any other components on the substrate 10.

A patterned tri-layered mask including a dielectric layer 44, a silicon-containing hard mask bottom anti-reflective coating (SHB) 46, and a patterned resist 48 is then formed sequentially on the dielectric layer 40 and the patterned etch mask 42. An opening 52, preferably a slot opening, is defined in the patterned resist 48. Preferably, a long axis of the opening 52 is perpendicular to a long axis of the patterned etch mask 42. In this embodiment, the dielectric layer 44 is composed of an organic dielectric layer (ODL), but not limited thereto. It should be noted that, as shown in FIG. 1, both of the dielectric layer 44 and the SHB 46 may have bumps on their top surfaces, especially on the top surfaces corresponding to the underlying patterned etch mask 42.

Referring to FIG. 2, an etching process P1 is then carried out by using the patterned resist 48 as an etch mask. During the etching process, the pattern of the patterned resist 48 may be transferred to the underlying SHB 46. It should be noted that the bump on the top surface of the dielectric layer 44 may still remain even though the SHB 46 is patterned during the etching process.

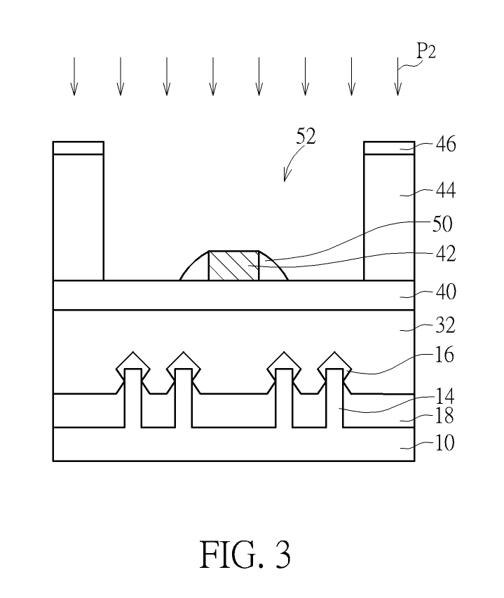

Referring to FIG. 3, another etching process P2 applied with etchants the same as or different form etchants applied in the above etching process P1 maybe performed. During the etching process, the pattern of the patterned resist 48 and the SHB 46 may be further transferred to the underlying dielectric layer 44 so as to form the opening 52 in the dielectric layer 44. In this embodiment, some of the dielectric layer 44, also called residues 50, may still remain on the sidewalls of the patterned etch mask 42 even though the pattern defined in the patterned resist 48 is completely transferred to the dielectric layer 44. The positions of the residues 50 are corresponding to the positions of the above-mentioned bumps. Because the residues 50 may reduce the cross-sectional area of the subsequently formed contact structures, the residues 50 should be completely removed before the formation of the contact structures. To this end, the duration of the etching process P2 is often extended so that all the residues 50 on the sidewalls of the patterned etch mask 42 may be removed successfully.

Referring to FIG. 4, an etching process P3 is performed by using the dielectric layer 44 and the patterned etch mask 42 as etch masks. During the etching process P3, the pattern defined by the dielectric layer 44 and the patterned etch mask 42 may be sequentially transferred to the dielectric layer 40 and the ILD layer 32. Accordingly, two contact openings 56 may be separately fabricated in the dielectric layer 40 and the ILD layer 32 at the sides of the patterned etch mask 42. Because each opening 52 can be used to define two contact openings 56 by the patterned etch mask 42, the patterned etch mask 42 is sometimes called “slot cut mask.” The contact openings 56 may expose the corresponding fin-shaped structures 14, or epitaxial layers 16, which may be electrically connected to the contact structures in the following process. In the following processes, the patterned etch mask 42 may be further completely removed, and the contact structures may be fabricated in the contact openings 56.

However, as shown in the lower figure of FIG. 4, the contours of the actual contact openings 56 are often different from the contours of ideal contact openings 58, and the former are often greater in area than the area of the later. That is to say, there is a deviation D between the actual contact openings 56 and the ideal contact openings 58. The reason of the enlargement in the contact openings 56 is that the bottom of the dielectric layer 44 is over etched during the process of removing the residues 50. Because of the enlargement in the contact openings 56, the uniformity or the critical dimension uniformity (CDU) of the contact openings 56 is inevitably worsened, which negatively affects the process of fabricating the contact structures.

In order to overcome the above-mentioned problem, the present disclosure also provides another method of manufacturing a semiconductor device and is disclosed in the following paragraphs. It should be noted that the description below is mainly focused on differences among each embodiment, and like or similar features will usually be described with same reference numerals for ease of illustration and description thereof.

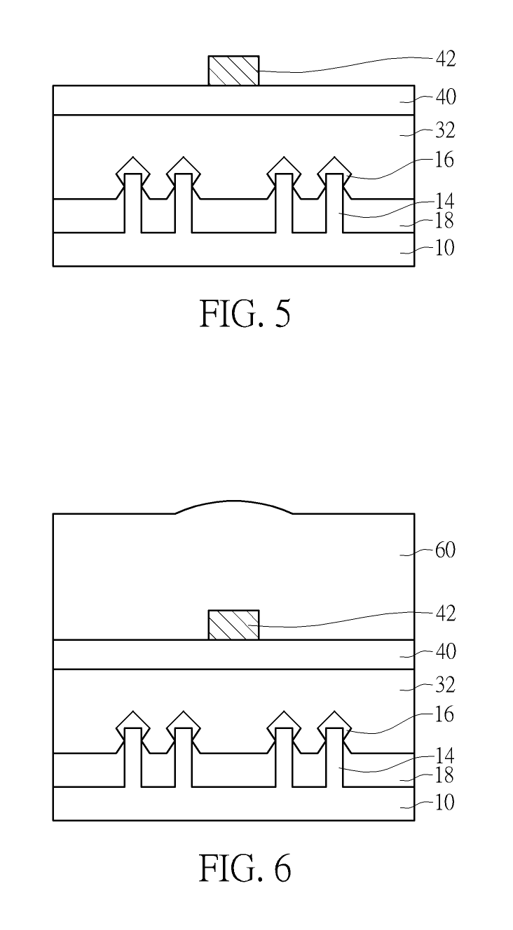

Referring to FIGS. 5-10, FIGS. 5-10 illustrate a method for fabricating a semiconductor device according to a second preferred embodiment of the present invention. As shown in FIG. 5, the substrate 10, such as a silicon substrate or silicon-on-insulator (SOI) substrate is provided, and the transistor region, such as a PMOS region or a NMOS region is defined on the substrate 10.

The first fin-shaped structures 14 and an insulating layer 18 are disposed on the substrate 10, in which the bottom of the fin-shapes structures 14 are preferably enclosed by the insulating layer 10, such as silicon oxide to form a shallow trench isolation (STI). The gate structure (not shown), such as the metal gate including the high-k dielectric layer, the work function metal layer and the gate electrode, crosses portions of every fin-shaped structure 14.

The source/drain region and/or epitaxial layers 16 are disposed on the fin-shaped structures 14 and/or substrate 10 adjacent to two sides of the spacer, a contact etch stop layer (CESL) (not shown) may be optionally formed on the dummy gates, and an interlayer dielectric (ILD) layer 32 composed of tetraethyl orthosilicate (TEOS) or other suitable dielectric materials is formed on the CESL.

The dielectric layer 40 is formed on the ILD layer 32 and the metal gate. The dielectric layer 40 may be an oxide layer composed of tetraethyl orthosilicate (TEOS), but is not limited thereto. It may also be composed of other suitable dielectric materials.

The patterned etch mask 42 is formed on the dielectric layer 40 and is used to define the positions of contact structures to be fabricated in the following processes. Specifically, the contact structures can only be formed in the ILD layer 32 not covered by the patterned etch mask 42. In addition, the patterned etch mask 42 may be made of any materials whose etching rates are less than one-third of the etching rates of the underlying layers, such as the dielectric layer 40, the ILD layer 32, and the CESL. Preferably, the patterned etch mask 42 is made of at least one of Ti, TiN, Ta, TaN or other conductive materials, but is not limited thereto. It should be noted that the patterned etch mask 42 may include several discrete masks separately disposed on the dielectric layer 40. These discrete masks are preferably electrically isolated from any other components on the substrate 10.

Referring to FIG. 6, a dielectric layer 60 made of materials the same as or similar to the material of the dielectric layer 40 is deposited or coated on the dielectric layer 40 and the patterned etch mask 42. Preferably, the dielectric layer 60 is TEOS and may also have a bump on its top surface, but is not limited thereto.

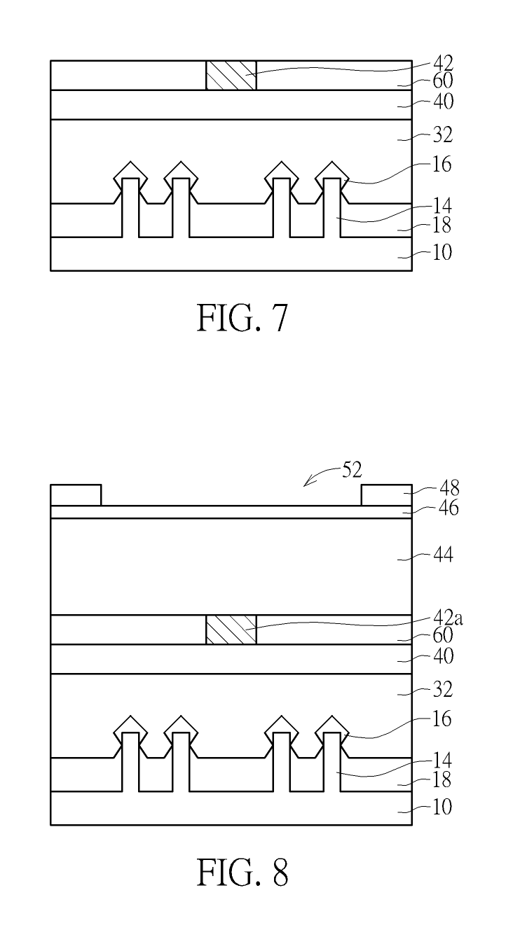

Referring to FIG. 7, the dielectric layer 60 is then planarized by a planarization process until the patterned etch mask 42 is exposed. Because of the polarization process, a top surface of the dielectric layer 60 may be substantially coplanar with a top surface of the patterned etch mask 42.

Then, referring to FIG. 8, the dielectric layer 44, the silicon-containing hard mask bottom anti-reflective coating (SHB) 46, and the patterned resist 48 are formed sequentially on the dielectric layer 40 and the patterned etch mask 42. The opening 52, preferably a slot opening, is defined in the patterned resist 48. In this embodiment, the dielectric layer 44 is also composed of an organic dielectric layer (ODL), but not limited thereto. It should be noted that the dielectric layer 44 and the SHB 46 being coated or deposited may have flat surfaces according to this embodiment because the top surfaces of the dielectric layer 60 and the patterned etch mask 42 are substantially coplanar.

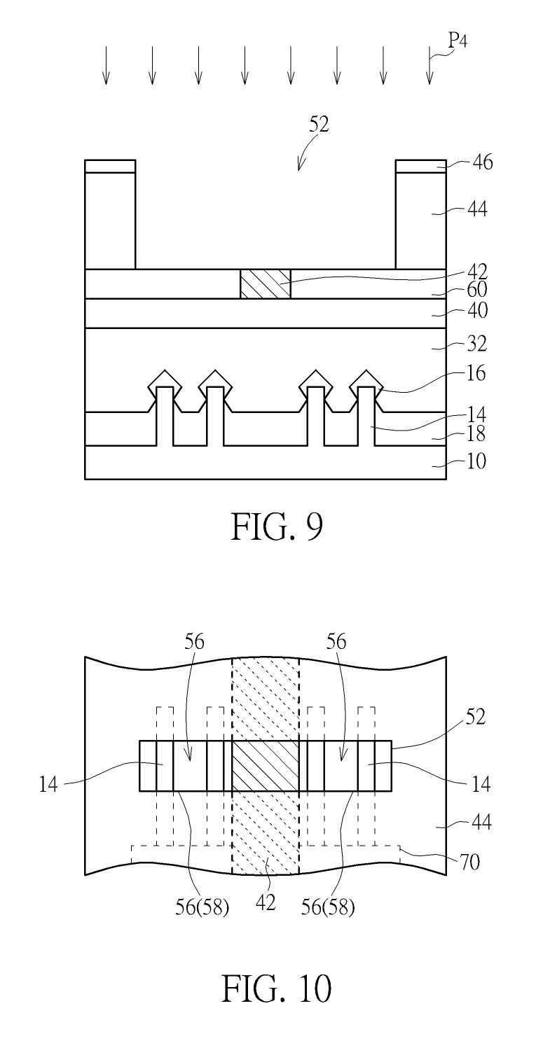

Referring to FIG. 9, an etching process P4 is then carried out by using the patterned resist 48 as an etch mask. During the etching process, the pattern of the patterned resist 48 may be transferred to the underlying SHB 46. It should be noted that the dielectric layer 60 exposed from the opening 52 may still have a flat surface. In other words, the opening 52 has a flat bottom at this fabrication stage.

After the top surface of the dielectric layer 60 is exposed to form the opening 52, another etching process may be performed, in which etchants being applied may be the same as or different form etchants applied in the above etching process P4. During the etching process, the pattern of the dielectric layer 44 and the patterned etch mask 42 maybe further transferred to the underlying dielectric layer 40 and the ILD layer 32.

When the above processes are completed, referring to FIG. 10, two contact openings 56 are separately fabricated in the dielectric layer 40 and the ILD layer 32 at the sides of the patterned etch mask 42. The contact openings 56 may expose the corresponding fin-shaped structures 14, or epitaxial layers 16, which may be electrically connected to the contact structures in the following process. It should be noted that, according to this embodiment, the contours of the actual contact openings 56 can match the contours of ideal contact openings 58. That is to say, there is almost no deviation D between the actual contact openings 56 and the ideal contact openings 58. Because there is no enlargement in the contact openings 56, the uniformity or the critical dimension uniformity (CDU) of the contact openings 56 can be improved compared with that disclosed in the first embodiment. Therefore, the yield rate in the process of fabricating the contact structures can be raised. In the following processes, the patterned etch mask 42 maybe completely removed, and the contact structures may be fabricated in the contact openings 56.

It should be noted that, although the composition of the dielectric layer 60 is the same as that of the underlying dielectric layer 40, the composition of the dielectric layer 60 may be the same as that of the above dielectric layer 44, e.g. ODL according another embodiment of the present disclosure. Because the processes of fabricating a semiconductor device with the dielectric layer 60 made of ODL are almost similar to the processes disclosed in the first and the second embodiments, the detailed description of which is omitted for the sake of clarity.

Those skilled in the art will readily observe that numerous modifications and alterations of the device and method may be made while retaining the teachings of the invention. Accordingly, the above disclosure should be construed as limited only by the metes and bounds of the appended claims.

1. A method of manufacturing a semiconductor device, comprising:
providing a semiconductor;
depositing a dielectric layer on the semiconductor;
forming a patterned etch mask on the dielectric layer;
depositing a further dielectric layer on the dielectric layer and the patterned etch mask so that an entire top surface of the further dielectric layer is higher than any part of a top surface of the patterned etch mask, wherein the further dielectric layer is in direct physical contact with the dielectric layer and the patterned etch mask;
planarizing the further dielectric layer until the patterned etch mask is exposed; and
forming a further patterned etch mask having an opening on the further dielectric layer, wherein portions of the patterned etch mask are exposed from the opening.

2. The method of claim 1, wherein a composition of the dielectric layer is the same as a composition of the further dielectric layer.

3. The method of claim 1, wherein the patterned etch mask is made of metal, alloy or ceramic material.

4. The method of claim 3, wherein the patterned etch mask is TiN.

5. The method of claim 1, wherein the further dielectric layer has a flat top surface before the step of forming the further patterned etch mask.

6. The method of claim 1, wherein the step of forming the further patterned etch mask comprises:
coating an organic dielectric layer on the further dielectric layer;
forming a patterned photoresist on the organic dielectric layer; and
etching the organic dielectric layer by using the patterned photoresist as an etch mask.

7. The method of claim 6, wherein there is no organic dielectric layer in the opening when the step of forming the further patterned etch mask is completed.

8. The method of claim 1, wherein the opening is a slot opening.

9. The method of claim 1, wherein the opening has a flat bottom.

10. The method of claim 1, further comprising performing an etching process by using the further patterned etch mask and the patterned etch mask as etch masks.

11. The method of claim 1, further comprising forming a contact opening in the dielectric layer and the further dielectric layer by using the patterned etch mask as an etch mask.

12. The method of claim 1, wherein a long axis of the patterned etch mask is perpendicular to a long axis of the opening.

13. The method of claim 1, wherein the patterned etch mask comprises a plurality of separately disposed masks.

14. The method of claim 1, wherein the semiconductor comprises a plurality of fin-shaped structures, the method further comprising forming at least two contact openings in the dielectric layer so that the fin-shaped structures are exposed from the bottom of the contact openings.

15. The method of claim 14, further comprising using the further patterned etch mask and the patterned etch mask as etch mask during the step of forming the contact openings.
